(19) United States
(12) Patent Application Publication
(10) Pub. No.: US 2013/0095327 A1
(43) Pub. Date: Apr. 18, 2013

(54) Device Comprising Deuterated Organic Interlayer

(71) Applicants: Zeev Valy Vardeny, Salt Lake City, UT (US); Leonard Wojcik, Holladay, UT (US); Tho Duc Nguyen, Salt Lake City, UT (US); Fujian Wang, Iowa City, IA (US)

(72) Inventors: Zeev Valy Vardeny, Salt Lake City, UT (US); Leonard Wojcik, Holladay, UT (US); Tho Duc Nguyen, Salt Lake City, UT (US); Fujian Wang, Iowa City, IA (US)

(73) Assignee: University of Utah Research Foundation, Salt Lake City, UT (US)

(21) Appl. No.: 13/497,499

(22) PCT Filed: Sep. 17, 2010
(86) PCT No.: PCT/US10/49228

§ 371 Date: Dec. 21, 2012

Related U.S. Application Data
(60) Provisional application No. 61/244,540, filed on Sep. 22, 2009.

(51) Int. Cl. H01F 10/08; H01F 41/14

(52) U.S. Cl. CPC H01F 10/08; H01F 41/14
USPC 428/419; 428/411.1; 428/704; 428/523; 428/457; 428/461; 427/58

(57) ABSTRACT

The present invention relates to devices that can be manipulated or controlled with a magnetic field, such as a spin-valve device, an organic light-emitting device, a compass, or a magnetometer. The devices of the invention comprise an organic interlayer comprising a deuterated organic material.

### CROSS REFERENCE TO RELATED APPLICATION

This application is based upon and claims the benefit of priority from prior U.S. Provisional Application Ser. No. 61/244,540, filed Sep. 22, 2009, the entire contents of which are incorporated herein by reference.

### ACKNOWLEDGEMENT

This invention was made with U.S. government support under Grant No. 04-ER46109 awarded by the United States Department of Energy. The U.S. government has certain rights in the invention.

### BACKGROUND

A spin valve is a layered structure of ferromagnetic materials and non-magnetic interlayer materials whose electrical resistance depends on the spin state of injected carriers passing through the device. A spin valve device can therefore be controlled by an external magnetic field. Other electronic devices, such as organic light emitting devices, compasses, and magnetometers can also be manipulated with an external magnetic field, since the resistance of the semiconducting layer in the device can be affected by a magnetic field.

It can be desirable for devices, such as spin valve devices and organic light-emitting devices, to comprise an organic interlayer as the semiconducting material and/or as the hole transport and emissive material if the device is of the electro-luminescent type. Organic materials are generally easier to process than inorganic semiconductors. Organic polymers, for example, can be spin-processed to form the device interlayers. The electronic structure of organic materials can also be tuned to thereby achieve a desired result, such as a desired emissive color.

However, spin states of electrons passing through an organic interlayer of a device such as a spin valve device or an organic light emitting device that is being modulated with an external magnetic field (or an organic light-emitting device that uses ferromagnetic electrodes) are believed to be affected by nuclear spins of atoms in the organic interlayer. This effect is believed to limit the efficiency of spin-dependent devices.

Therefore, a need exists for improved spin valve and other electronic devices, including organic light emitting devices. This need and other needs are satisfied by embodiments of the present invention.

### SUMMARY

Embodiments of the present invention generally relate to devices of the electrical, electroluminescent, and magnetic type which can be manipulated with a magnetic field. The disclosed devices comprise an organic interlayer comprising a deuterated organic material. Without wishing to be bound by theory, it is believed that the deuterated organic material reduces spin-dependent effects between injected carriers and protonated hydrogen atoms present in the organic interlayer having nuclei with a spin=½.

In one aspect, a disclosed device comprises first and second electrodes; and an organic interlayer between the first and second ferromagnetic electrodes, the organic interlayer comprising a deuterated organic material.

Also disclosed is a method of forming a device, comprising: forming a first electrode; forming an organic interlayer on at least a portion of the first electrodes, the organic interlayer comprising a deuterated organic material; and forming a second electrode, wherein said organic interlayer is at least partially between the first and second electrodes.

Additional advantages will be set forth in part in the description which follows, and in part will be obvious from the description, or may be learned by practice. Other advantages will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE FIGURES

The accompanying figures, not necessarily drawn to scale, which are incorporated in and constitute a part of this specification, illustrate several embodiments and together with the description serve to explain the principles of the invention, and in which:

FIG. 1 is a diagram of an exemplary configuration of an organic spin valve device;

FIG. 2 is a diagram of an exemplary configuration of an organic light-emitting device;

FIG. 3 is a diagram of another aspect of the exemplary configuration of an organic light-emitting device;

FIG. 4 is a diagram of yet another aspect of the exemplary configuration of an organic light-emitting device;

FIGS. 5a-d show isotope dependence of magnetoresistance (MR) in organic spin valves based on DOO-PPV polymers; (a,b) MR loop of LSMO (200 nm)/DOO-PPV (30 nm)/Co (15 nm) spin-valve device measured at 10 K and V=20 mV, based on (a) D- and (b) H-polymers where the curves denote MR measurements made while increasing or decreasing B, the nominal resistance is ˜120 and ˜90 kΩ, respectively for the D- and H-polymers OSVs, the antiparallel (AP) and parallel (P) configurations of the FM magnetization orientations are shown in the insets at low and high B, respectively; the electrical resistance of the device is higher when the magnetization directions in FM1 and FM2 films are antiparallel (AP) to each other, (c) the maximum MR value, (MRSV) of the OSV devices shown in a and b, as a function of the applied bias voltage, V, measured at 11 K; y-scale is logarithmical; (d) normalized MRSV of the OSVs shown in a and b as a function of temperature, measured at V=80 mV;

FIGS. 6a-d show isotope dependence of magneto-electroluminescence (MEL) response in OLEDs based on DOO-PPV polymers; (a, b) room temperature MEL response of D- and H-polymers measured at bias voltage V=2.5 volt, plotted on large (a) and small (b) magnetic field scales, where the respective regular and small-field MEL responses are separated; inset to (a): the half width at half maximum (HWHM) of the regular MEL response for the two polymers as a function of the applied bias voltage, V, given in terms of the internal electric field in the polymer layer, where V_{bi} is the built-in potential in the device; the lines are linear fits; (c, d) simulations of the MEL in the two polymers reproducing the response data in (a, b) based on a model using calculated spin sublevels;

FIGS. 7a, 7b and 7c show a compass configuration based on the magneto-conductivity of an OLED based on a D-DOO-PPV polymer. The compass configuration: B(Earth) is the earth magnetic field, B(magnetite) is the internal field inside the device. The angle α is in the XY plane. 7b: The magnetoconductivity (MC) of the device as a function of the angle, α; the compass shows minimum MC when the internal field is parallel to the Earth field direction. 7c: The calibrated MC(α) response;

FIG. 8 is a plot showing the MC(B) response of a shielded OLED device; and

FIG. 9 is a plot showing the MC(B) response of an unshielded device that is subject to the influence of the Earth magnetic field, aligned parallel or antiparallel to the applied field. The deviation of the MC(B) internal peak from zero field value can be used to accurately determine the external field, B(external). In this case B(external)=0.5 Gauss.

### DETAILED DESCRIPTION

The devices, systems and methods described herein may be understood more readily by reference to the following detailed description and the examples included therein and to the figures and their previous and following description.

Before the present systems, articles, devices, and/or methods are disclosed and described, it is to be understood that this invention is not limited to specific systems, specific devices, or to particular methodology, as such may, of course, vary. It is also to be understood that the terminology used herein is for the purpose of describing particular embodiments only and is not intended to be limiting.

The following description of the invention is provided as an enabling teaching of the invention in its best, currently known embodiment. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the embodiments of the present invention without utilizing other features. Accordingly, those who work in the art will recognize that many modifications and adaptations to the present invention are possible and can even be desirable in certain circumstances and are a part of the present invention. Thus, the following description is provided as illustrative of the principles of the present invention and not in limitation thereof.

Although any methods and materials similar or equivalent to those described herein can be used in the practice or testing of the present invention, example methods and materials are now described.

Throughout this application, various publications are referenced. Unless otherwise noted, the disclosures of these publications in their entireties are hereby incorporated by reference into this application in order to more fully describe the state of the art to which this pertains. The references disclosed are also individually and specifically incorporated by reference herein for the material contained in them that is discussed in the sentence in which the reference is relied upon. Nothing herein is to be construed as an admission that the present invention is not entitled to antedate such publication by virtue of prior invention. Further, the dates of publication provided herein may be different from the actual publication dates, which may need to be independently confirmed.

As used in the specification and the appended claims, the singular forms “a,” “an” and “the” include plural referents unless the context clearly dictates otherwise. Thus, for example, reference to “a device,” “a layer,” or “a polymer” includes combinations of two or more such devices, layers, or polymers, and the like.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that when a value is disclosed that “less than or equal to” the value, “greater than or equal to the value” and possible ranges between values are also disclosed, as appropriately understood by the skilled artisan. For example, if the value “10” is disclosed the “less than or equal to 10” as well as “greater than or equal to 10” is also disclosed. It is also understood that throughout the application, data is provided in a number of different formats and that this data represents endpoints and starting points, and ranges for any combination of the data points. For example, if a particular data point “10” and a particular data point 15 are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

As used herein, the terms “optional” or “optionally” means that the subsequently described aspect may or may not be present or that the subsequently described event or circumstance may or may not occur, and that the description includes instances where said event or circumstance occurs and instances where it does not. For example, a disclosed organic light-emitting device can optionally comprise a distinct emissive layer between a hole-transport and an electron-transport layer, i.e., an emissive layer can or cannot be present.

“Exemplary,” where used herein, means “an example of” and is not intended to convey a preferred or ideal embodiment. Further, the phrase “such as” as used herein is not intended to be restrictive in any sense, but is merely explanatory and is used to indicate that the recited items are just examples of what is covered by that provision.

“Device” as used herein, refers to any device comprising a disclosed deuterated organic material between at least two electrodes. The “device” can be an organic spin valve device, an organic light-emitting device (or diode) (OLED), a compass, a magnetometer, and the like.

Disclosed are the components to be used to prepare the compositions as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of polymers A, B, and C are disclosed as well as a class of polymers D, E, and F and an example of a combination polymer, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the devices. Thus, if there are a variety of additional steps that can be performed it is understood that each of these additional steps can be performed with any specific embodiment or combination of embodiments of the methods.

It is understood that the devices disclosed herein have certain functions. Disclosed herein are certain structural requirements for performing the disclosed functions, and it is understood that there are a variety of structures that can perform the same function that are related to the disclosed structures, and that these structures will typically achieve the same result.

The present invention generally relates to devices comprising a deuterated organic material as an interlayer. As briefly discussed above, the device can be any device that utilizes a semiconductor layer. By using the deuterated organic material as part of or all of an organic interlayer in such a device, device performance can be improved, particularly if the device is being manipulated with a magnetic field, which practice is commonly used in memory storage devices, such as organic spin valve devices. Two examples of such devices are organic spin valve devices and organic light-emitting devices. The performance of these devices in the presence of a magnetic field is improved by using the disclosed deuterated organic material.

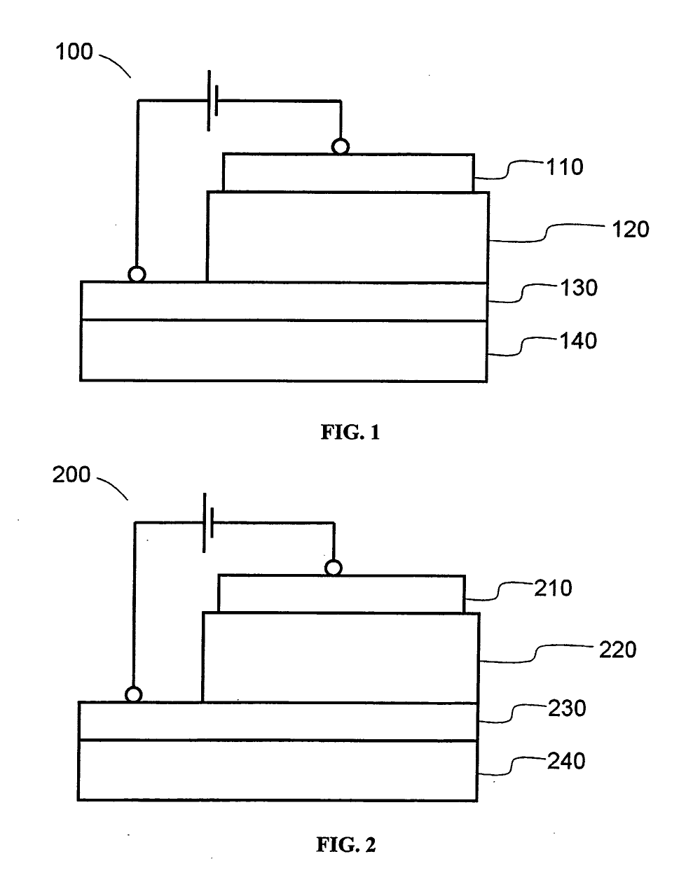

An organic spin valve device can be arranged vertically or laterally. For example, with reference to FIG. 1, a vertically arranged organic spin valve device 100 comprises first 110 and second 130 ferromagnetic electrodes. An organic interlayer 120 is positioned between the first 110 and second 130 ferromagnetic electrodes. The organic spin valve device can also include a substrate 140 below the second 130 ferromagnetic electrode.

The first and second electrodes can comprise the same or different materials. In laterally arranged devices, the first and second electrodes can comprise the same material, but should preferably have different widths to better control magnetization switching in each electrode independently. Alternatively, the electrodes can comprise different materials, which can be preferable in a vertically arranged device.

When the first and second electrodes comprise different materials, the first and second materials can be selected to have a different coercive field, H_{c} (see Fert, A. Nobel Lecture: Origin, development, and future of spintronics. Rev. Mod. Phys. 80, 1517-1530, 2008, incorporated by reference herein). With two electrodes having a different coercive field, it is possible to switch the relative magnetization directions of the ferromagnetic electrodes from parallel to anti-parallel alignment (and vice versa), upon sweeping the external magnetic field, B. In spin-valve devices, the resistance is typically higher for the anti-parallel magnetization orientation, which is believed to be due to spin injection and transport through the spacer layer.

Any metal, alloy or semiconductor can be used in the first and second electrodes, which again can be the same or different. Non-limiting examples include Co, Ni, Fe, and alloys thereof. The electrodes can also be half-metallic, for example, ReMnO₃, or CrO₂. The electrodes can also be semiconducting, for example, GaMnAs. In one example, a vertically arranged spin-valve device comprises a ferromagnetic oxide adjacent to the substrate (130 in FIG. 1), such as La_{2/3}Sr_{1/3}MnO₃ (LSMO), and a Co-based electrode as the first ferromagnetic electrode (110 in FIG. 1). The Co-based electrode can be pure Co, an alloy of Co, or a composite of Co and another metal, such as Al. For example, the Co-based electrode can comprise a bilayer of Co and Al. In many of the disclosed examples, the first and second electrodes are ferromagnetic.

For a vertically-arranged organic spin-valve device, the ferromagnetic layers will typically be a high-melting temperature material, whereas the organic semiconducting layer has typically a low melting temperature. Accordingly, during the ferromagnetic (FM) electrode deposition process, the deposition temperature needs to be much lower than the melting point of the organic materials if the organic materials have been already deposited. Higher temperatures may evaporate the organic film away or cause intermixing between the organic and FM materials that would deteriorate their internal magnetization. As a result the intermixing at the FM/organic interfaces can impair the magnetoresistance.

Metallic ferromagnetic electrodes also typically oxidize in air. The oxidized interfaces can impair magnetoresistance in the final devices. It is therefore advantageous to fabricate the metallic electrodes together with the organic semiconductors in vacuum. Sputtering (a common deposition technique) is not preferred for the metallic electrode deposition if the organic layer is already deposited because the plasma is detrimental to the organic semiconductors. Film deposition is preferably carried out in vacuum at low temperatures. For some spin-injecting electrodes such as the ferromagnetic oxides (e.g. LSMO), in-situ deposition is not required in fabricating the organic spin-valve since they do not react with oxygen. Such electrodes can be predeposited, cleaned and then introduced into the vacuum chamber prior to the organic and the second electrode deposition.

Various methods known in the art for fabricating the organic spin valve devices can be used. According to one exemplary method, one ferromagnetic electrode (FM1) is a pre-substrate-deposited ferromagnetic electrode that is not air sensitive. The organic interlayer is then deposited on FM1 by thermal evaporation at a relatively low temperature, whereas the deposition of the other ferromagnetic layer, FM2 is done by thermal evaporation with cooled substrates and/or with a cooled region near the evaporation source so that the excess heat can be taken away. This ensures that the vacuum chamber is at a sufficiently low temperature that the deposited organic layer will not evaporate away or intermix with FM2 at the interface. The thermal evaporation of FM2 can be replaced with electron-beam evaporation, which typically produces less heat if the evaporation is from a focused spot.

Another method involves depositing a very thin FM2 layer (thickness of the order of few nm) onto the organic layer so that the high deposition temperature will only be needed for a relatively short time. A thin layer (˜1 nm or so) of ferromagnetic material is already adequate to establish its ferromagnetism at the interface in order to produce the magnetoreistance. If a relatively thick organic layer is first deposited, some of it would evaporate away during the FM2 layer deposition, but some would remain deposited on the first predeposited FM1 layer. To ensure electrical connection and to protect the relatively thin FM2 layer, a low melting temperature metal (e.g. Al, Au) is evaporated on top of FM2, for example, Al deposited onto Cu.

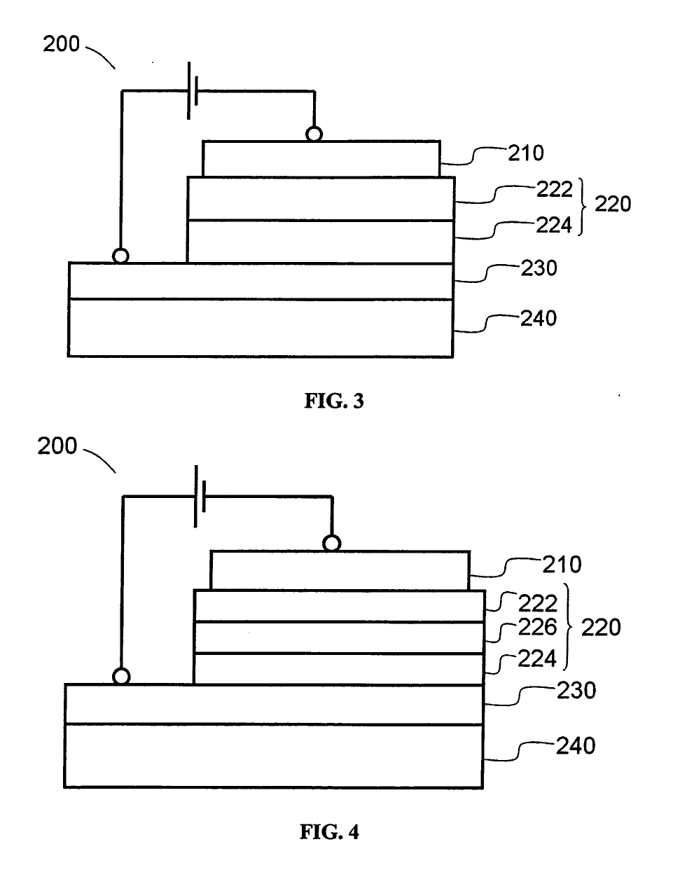

An organic light-emitting device can be configured according to the example shown in FIG. 2, wherein the organic interlayer comprises a single layer 220 deposited onto an anode 230 with a cathode 210 deposited onto the deuterated organic interlayer 220. A substrate is typically below the anode 230. A single organic interlayer in such a basic device can both transport injected carriers and produce electro-luminescence. Alternately, additional layers can be incorporated into the general device structure of FIG. 2, as is known in the art. For example, with reference to FIG. 3, the device 200 can further comprise a hole-transport layer 224 deposited on top of the anode 230, which is deposited on top of a substrate 240. The deuterated organic material (electron-transport layer) 222 can be deposited on top of the hole-transport layer 224, followed by the deposition of the cathode 210. In another aspect, with reference to FIG. 4 an additional emissive layer 226 can be present.

The organic light-emitting device can also serve as the basis for a compass device and a magnetometer device. For a compass device, a magnet, preferably magnetite, is attached to the OLED. A magnetometer, as discussed in more detail below, can also be prepared using the OLED. The magnetometer can be shielded and can be used to detect magnetic fields.

With multi-layered devices, such as the device depicted in FIG. 3 and FIG. 4, the anode and cathode can be conventionally coated with electron transporting and/or hole transporting organic materials. For a device as depicted in FIG. 4, for example, recombination of injected carriers often occurs near the interface(s) of the emissive layer. In such devices, improved device performance, including device lifetime, can be achieved by moving the recombination area away from a metal-organic interface to an organic-organic interface. Hence, a hole transport layer can be added close to the anode, and an electron transport layer added close to the cathode. Other devices can also contain multiple emissive films, such as for multicolor or white emitting devices, such as in SOLEDs (stacked organic LEDs).

The organic light-emitting device of the invention also comprises at least two electrodes with a deuterated organic material in between the electrodes. A variety of electrodes can be used for this device. The electrodes can be either ferromagnetic or non-ferromagnetic. If non-ferromagnetic electrodes are used, the device can still be manipulated with an external magnetic field through the use of an external magnetic material. Alternatively, the electrodes of the organic light-emitting device can be ferromagnetic. Any conventional ferromagnetic or non-ferromagnetic electrode can be used with the organic light-emitting device. In one example, indium-tin oxide (ITO) is used as the anode, while Ca/Al is used as the cathode.

The hole-transport material, if present, can be any hole-transport material used in organic light-emitting devices. One non-limiting example of a hole-transport material is poly(3,4-ethylenedioxythiophene) [PEDOT]-poly(styrene sulphonate) [PSS]. Likewise, a variety of conventional emissive materials can be used as desired. Examples include polymers such as polythiophenes, metal complexes, porphyrins, among others. In some aspects, the deuterated organic material itself may be electro-luminescent.

The efficiency of an organic light-emitting device can be improved by increasing the spin flip rate (or reducing the spin relaxation time) of carriers in a light emitting layer by the addition of spin-carrying impurities, such as ions (such as Fe³⁺ and Ti³⁺), molecules, radicals, molecular substituents, complexes, iron, or other magnetically active impurities. The concentration of such impurities is preferably not high enough to significantly enhance the non-radiative recombination of singlet excitons. Molecular and polymer based molecular magnetic materials are also known in the art, and may be added to emissive layers in embodiments of the present invention.

An emissive layer can also be doped with an impurity (or otherwise modified) so as to increase the spin-lattice relaxation rate (decrease the spin-lattice time), and hence increase the efficiency. The impurity is preferably a paramagnetic substance. Paramagnetic substances include transition metals (such as iron, manganese, and cobalt), lanthanides, actinides, and other certain alloys and compounds. The impurity can be selected from known paramagnetic shift reagents used in nuclear magnetic resonance spectroscopy.

Impurities such as iron, cobalt, manganese, other transition metals, transition metal alloys, and transition metal compounds can be added to the emissive layer in the form of microparticles, microrods, nanoparticles, metal complexes, doped glasses, ceramics, other compounds, clusters, or other structures. For example, an organic light-emitting device can comprise a layer of an electro-luminescent compound, such as a light emissive complex, doped with an iron complex. Particles can be coated with an electrically insulating layer to help prevent short circuits.

Methods for making the organic light-emitting devices of the invention are known in the art. For example, a vertically arranged organic light-emitting device can be made according to methods similar to those for organic spin valve devices, wherein an electrode is deposited onto a substrate, such as a glass or ITO substrate, followed by the deposition of the organic interlayer, followed by the deposition of the cathode material.

Methods for using the devices of the invention are known. The devices are useful in memory systems such as those present in computers, as magnetic sensors and magnetic field detectors, lighting displays (for electro-luminescent devices), among several other applications.

The deuterated organic material of the device can be a polymer or small molecule. In one aspect, the deuterated organic material is a deuterated analog of a material typically used as in an organic interlayer of an organic spin valve device or an organic light-emitting diode. Without wishing to be bound by theory, it is believed that hyperfine interactions (HFI) between injected carriers that have a spin of ½ and various nuclear spins present in the organic interlayer, such as those also having a spin of ½, can impair device performance. The present invention may achieve improved performance by minimizing the amount of atoms in the organic interlayer of which nuclei have a spin of ½, particularly hydrogen (¹H), and replacing these atoms with deuterium, which has a spin of 1 and a small HFI constant. Therefore, a variety of materials typically used in organic spin valve devices and organic light-emitting diodes can be improved by replacing at least some of the hydrogen atoms present on the organic material with deuterium.

In one aspect, the organic interlayer comprises a substantial number of atoms having a spin of 1, such as deuterium atoms. In a further aspect, the organic interlayer has a deuterium atom: hydrogen atom ratio of at least 0.1:100, 1:100, 10:100, 50:100, and up to 100:0. In one specific aspect, most or all of the hydrogen atoms on the backbone carbon atoms in π-conjugated polymers can be replaced with deuterium. These hydrogen atoms on the backbone of the polymer are closest to the injected carriers and therefore can be desirable to replace with deuterium. Hydrogen atoms farther from the polymer backbone (such as those on a side-chain) can also be replaced with deuterium if desired. Also desirable for deuterium replacement are those hydrogen atoms farthest from the center of small organic molecules.

In some aspects, certain materials commonly used in the organic interlayer of devices are not preferable. Typically, these materials will be such that even if the hydrogen atoms were replaced with deuterium, the materials may still be undesirable. Deuterated aluminum-tris-8-hydroxyquinoline (Alq₃) is an example of such a material. Without wishing to be bound by theory, Al has a nuclear spin of 5/2, and therefore may contribute to hyperfine interactions (HFI) with injected carriers. Thus, even a deuterated version of Alq₃, in some aspects, is undesirable. In some aspects, it is desirable for the organic interlayer to not comprise a substantial amount of heavy atoms due to the inclusion of spin-orbit coupling. The deuterated material can also consist of deuterium and one or more elements selected from carbon, hydrogen, nitrogen, sulfur, and oxygen.

Examples of suitable deuterated materials include partially or fully deuterated organic semiconductors, including partially or fully deuterated organic semiconducting polymers (e.g., π-conjugated polymers). Non-limiting examples include pentacenes, phthalocyanines, perylenes, quinolines, polymers thereof; and poly(p-phenylenevinylenes) (PPV), poly(thiopene)s, polyacetylenes, polypyrroles, polyanilines, polyphenylene sulfides, among others.

In one specific aspect, the polymer is a deuterated PPV. An example of such a deuterated PPV is a PPV corresponding to the following structure:

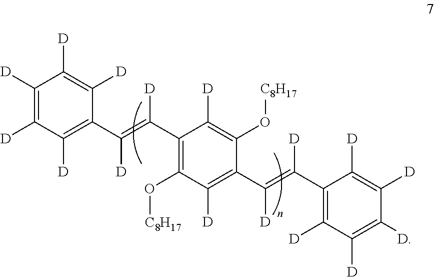

Generally, any poly(dialkyloxy)phenyl vinylene can be used as the deuterated organic material (the example above is poly(dioctyloxy)phenyl vinylene). The alkyl group of the PPV can be a C1-C18 alkyl group, such as methyl, ethyl, propyl, butyl, pentyl, hexyl, heptyl, octyl (as shown above), nonyl, decyl, and the like. Each of these alkyl substituted deuterated PPVs can be made according to Scheme 1 shown below, by varying the alkyl bromide that reacts with the corresponding deuteroxide shown in the second step of Scheme 1, Part A.

The deuterated organic material can be made by methods known in the art or methods disclosed herein. Typically, hydrogen atoms of a material can be replaced using D⁺ in a deuterated solvent, such as D₂O. Other nuclear replacement methods known in the art can also be used.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1

### Preparation of a Deuterated Organic Material

Synthetic reagents and solvents were procured from Aldrich Chemical as reagent grade and used as received. The deuterium oxide used was of 99.8% purity. Glassware used was standard taper fitted with NYE sealing sleeves so as to avoid grease contamination. NMR data was obtained using a Varian Inova 400 MHz instrument Infrared spectra were obtained using a Bruker IFS-88 FTIR. Chemicals and reagents were obtained from Aldrich Chemical and used as received, unless otherwise noted. An exemplary deuterated organic material, deuterated dioctyloxypolyphenylvinylidine, was prepared according to Scheme 1.

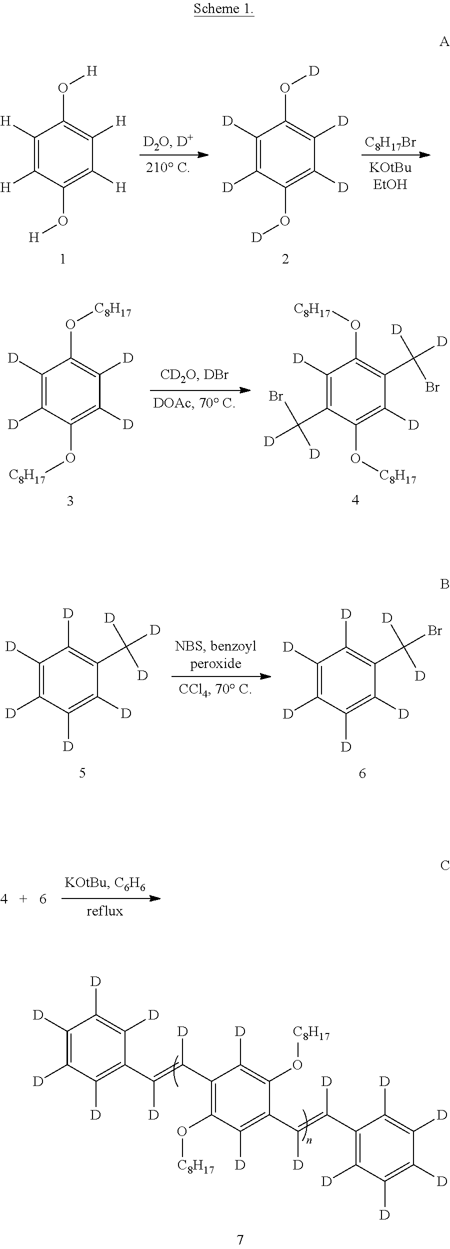

Hydroquinone-d₆ (2) was prepared by three successive exchanges of hydroquinone with 99.8% D₂O in the presence of acid, according to a modification of a method described by Xu [K. Xu, J. C. Selby, M. A. Shannon, J. Economy, J. Applied Polymer Science 92, 3843 (2004)]. The reaction was carried out in an autoclave at 210° C. 1,4-dioctyloxybenzene-d₄ (3) was prepared by a Williamson synthesis with the potassium salt of hydroquinone-d₆ with 1-bromooctane in absolute ethanol. 2,5-bis(bromomethyl)-1,4-dioctyloxybenzene-d₆ (4) was prepared according to the technique described by Zhang et al [K. Fesser, A. R. Bishop, and D. K. Campbell, Phys. Rev. B27, 4805 (1983)], using 1,4-dioctyloxybenzene-d4 (4), paraformaldehyde-d2, Acetic acid-OD and 48% deuterium bromide in D₂O. Benzylbromide-d₇ (6) was prepared by bromination of toluene-d₈ with N-bromosuccinimide and benzoyl peroxide in carbon tetrachloride. Dioctyloxypolyphenylvinylidine backbone deuterated (DOO-PPV-d) (7) was prepared by polymerization of (4) with potassium t-butoxide in refluxing benzene in the presence of Benzylbromide-d₇ in a 1:20 ratio of (6) to (4).

Shorter polymers (or oligomers) of DOO-PPV tend to be more soluble in solvents such as toluene, and do not gel out easily. To make shorter polymers or oligomers, a deuterated benzyl bromide (6) can be used as an endcap. Alternatively, a polymerization of 2,5-bis(chloromethyl)-1,4-dioctyloxybenzene with potassium t-butoxide in refluxing p-xylene can be used. This route allows some control of the polymer chain length, since the reaction is relatively slow [see, e.g., F. Wudl, and G. Srdanov, U.S. Pat. No. 5,189,136].

Attempts to polymerize the bis-bromomethyl derivative with THF as a solvent led to long polymer chain lengths, which in some cases formed gels. The gelling effect was reduced by use of refluxing benzene as the polymerization solvent, where the reaction can be monitored and stopped when a desired level of polymerization is reached.

For comparison, a hydrogenated analog of the deuterated DOO-PPV was studied (H-DOO-PPV). The deuterated polymer (D-DOO-PPV) was characterized using NMR studies and Raman scattering. The two main Raman-active bands of H-DOO-PPV at ˜1300 cm⁻¹ and 1500 cm⁻¹ were red shifted by about 3% upon deuteration. These lines are mainly due to the intrachain C—C and C═C stretching vibrations, respectively; since the excitation laser frequency used (488 nm) is in resonance with the polymer optical gap, the Raman intensity of these backbone vibrations is resonantly enhanced. The Raman spectrum does not contain any splitting of the Raman active modes, which would indicate mixtures of D- and H-atoms on the backbone. Moreover, the ˜3% red shift is in line with the expected isotope shift due to the ‘square root of the mass ratio’ [Vardeny, Z. V., Brafman O. & Ehrenfreund E. Isotope effect in resonant Raman scattering and induced IR spectra of trans polyacetylene. Solid State Commun. 53, 615-620 (1985)], namely [m(CD)/m(CH)]^{1/2}≈1.037. The photoluminescence (PL) band of the two DOO-PPV polymers is essentially the same, apart from the phonon replica that are red shifted and weaker in the D-polymer due to the different intrachain vibrations in the two materials. This confirms that the polymer electronic structure, and therefore also the photoexcitation species such as excitons, polarons and polaron pairs are essentially the same in the two DOO-PPV polymers.

### Example 2

### Optically-Detected Magnetic Resonance, ODMR

For measuring optically-detected magnetic resonance, the polymer sample is placed in a high Q (˜10³) cavity in a cryostat at 10 K, which is equipped with MW throughput cables, suitable for 3 GHz MW provided by a Gunn diode delivering power of ˜100 mW [Yang, C. G., Ehrenfreund, E. & Vardeny, Z. V. Polaron spin-lattice relaxation time obtained from ODMR dynamics in π-conjugated polymers, Phys. Rev. Lett. 99, 157401 (2007)]. The cryostat is placed between the two poles of a magnetic field up to 3 Tesla perpendicular to the sample film, which is provided by a superconducting coil cooled at liquid He temperature. A constant power laser beam of ˜200 mW pumps the sample PL emission, which is measured by a Si detector. The MW power is modulated at frequency, f˜200 Hz, and the changes, SPL in PL intensity are monitored using a lock-in amplifier at f. The magnetic field is swept while monitoring δPL; resonance condition for spin ½ occurs when the MW photon energy is equal to the energy difference between the two Zeeman split spin sublevels, which occurs at ˜0.1 Tesla for an S-band. δPL>0 because the PP recombination rate increases at resonance conditions due to spin mixing in the spin sublevels, induced by MW absorption. For the deuterated polymer described in Example 1, δPL at resonance was measured, as a function of the MW power P_{MW} for obtaining the ODMR saturation and linewidth broadening with P_{MW}.

### Example 3

### Organic Spin Valve Device

Exemplary organic spin valves (OSV) were fabricated using both deuterated DOO—PPV and hydrogenated DOO-PPV (for comparison) as spacers in between two ferromagnetic (FM) electrodes. The two ferromagnetic electrodes were La_{0.67}Sr_{0.33}MnO₃ (LSMO) for the bottom electrode (FM₁), and cobalt (Co) as the top electrode (FM₂). The LSMO films with thickness of ˜200 nm and area of 5 mm×5 mm, were grown epitaxially on <100> oriented SrTiO₃ substrates at 735° C. using dc magnetron sputtering technique, with Ar and O₂ flux in the ratio of 1:1. The films were subsequently annealed at 800° C. for ˜10 hours before cooling down to room temperature at a slow rate. The LSMO films were subsequently patterned using standard photolithography and chemical etching techniques. Contrary to cobalt, the LSMO films are already stable against oxidation; LSMO films have been cleaned and re-used multiple times without any apparent degradation [Xiong, Z. H., Wu, D., Vardeny, Z. V. & Shi, J. Giant magnetoresistance in organic spin-valves. Nature 427, 821-824 (2004)]. After cleaning the LSMO substrate with chloroform, the polymer layer was deposited by spin casting from a 6 mg/ml 1,2-dichlorobenzene solution. Subsequently, the hybrid organic/inorganic junction was introduced into an evaporation chamber with a base pressure of 5×10⁻⁷ torr. In the chamber, a thin (10-20 nm) Co film was followed by an aluminium (Al) film for protection and contact, using a shadow mask. The obtained active device area was about 0.2 mm×0.4 mm.

Several OSV devices were fabricated having various organic thicknesses, d_{f} between 20 to 80 nm. Deuterated DOO-PPV and hydrogenated DOO-PPV based OSV having same thickness were measured and compared at various biasing voltage, V and temperature T. The polymer film thickness was measured outside the chamber by thickness profilometry (KLA Tencor). The I-V characteristic of the OSV devices was non-linear with weak temperature dependence, indicative of carrier injection by tunnelling. Typical device resistance was of the order of hundred kΩ. The magnetoresistance of the fabricated devices was measured in a closed-cycle refrigerator from 10 to 300 K using the ‘four probe’ method, while varying an external in-plane magnetic field. The magnetization properties of the FM electrodes were measured by the magneto-optic Kerr effect (MOKE); from these measurements the low temperature coercive fields H_{c1}˜4 mT and H_{c2}˜10 mT were estimated, for the LSMO and Co film electrodes, respectively.

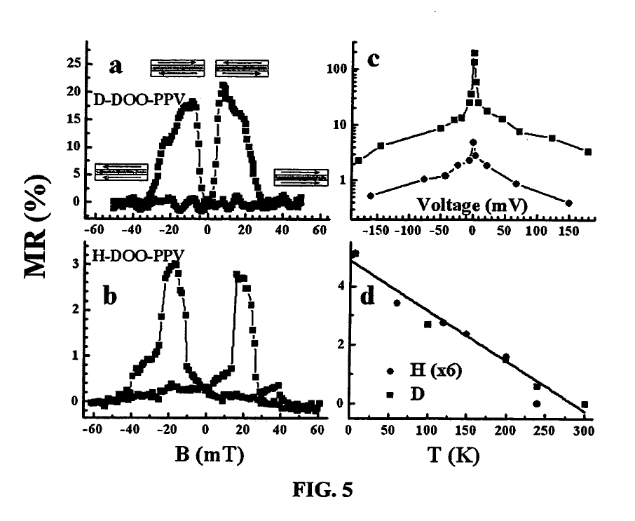

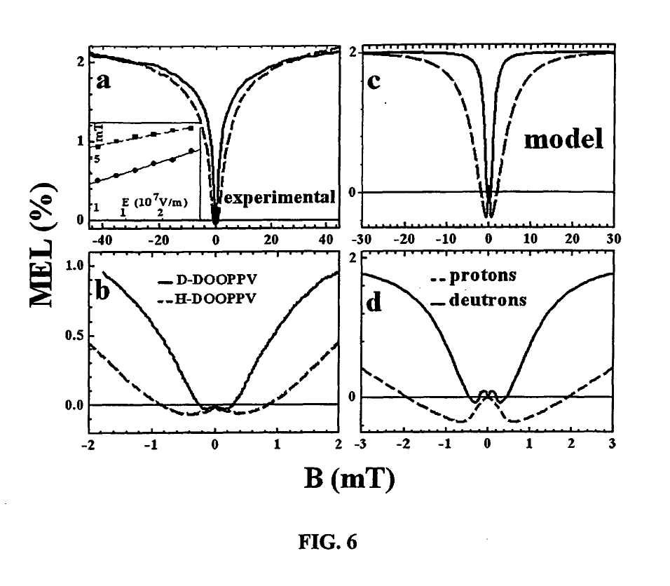

For the spin injection and transport investigations comparing the H- and D-polymers, OSV devices were used where the polymer film was sandwiched between two ferromagnetic (FM) electrodes with different coercive field, H_{c}. These are La_{2/3}Sr_{1/3}MnO₃ (LSMO) and Co thin films, with low temperature H_{c1}≈4 mT and H_{c2}≈10 mT, respectively; and nominal (according to the literature) spin injection polarization degree P₁≈95% and P₂≈−40%⁶. Since H_{c1}≠H_{c2}, it is possible to switch the relative magnetization directions of the FM electrodes from parallel (P) to anti-parallel (AP) alignment (and vice versa), upon sweeping the external magnetic field, B (see FIGS. 5a and 5b); the device resistance depends on the relative magnetization orientations. In spin-valve devices the resistance is usually higher for the AP magnetization orientation, which is due to spin injection and transport through the spacer layer. When R(AP)>R(P), the maximum MR value, [ΔR/R]ₘₐₓ (or MR_{SV}) is given by the ratio: [R(AP)−R(P)]/R(P); which according to a modified Julliere formula is related to the FM electrodes P₁ and P₂ by the following formula:

[ΔR/R]ₘₐₓ=2P₁P₂D/(1−P₁P₂D),

In the above equation D=exp[−(d_{f}−dₒ)/λₛ], where λₛ is the spin diffusion length in the organic interlayer, d_{f} is its thickness, and dₒ (is of order ˜5 nm in polymers) is an “ill-defined” organic layer thickness, where inclusions of the upper FM metal (Co) may be abundantly found. The MR hysteresis loop was measured to obtain the MR_{SV} value in OSVs based on the two polymers at various biasing voltage, V and temperature, T, using the same LSMO substrate; this was possible since the LSMO substrate is stable in air, and its spin injection properties were found to be robust. For comparing the OSV performance of the two polymers it is important to measure devices with same interlayer thickness d_{f} that were prepared similarly; thus the device fabrication procedure was strictly obeyed and d_{f} was carefully measured.

FIGS. 5a and 5b show representative MR hysteresis loops for two similar OSVs based on H- and D-polymers, respectively at T=10 K and V=20 mV. A positive MR was obtained for the devices, where R(AP)>R(P); this is opposite to the inverse (or negative) MR that was measured before in OSVs based on evaporated layers of small organic molecules, such as Algₐ. The MR sign may be positive or negative depending on the orientation, age and growth of the LSMO substrate. The devices based on the D-polymer have much larger MR_{SV} value than those based on the H-polymer. This holds true at any V and T, as seen in FIGS. 5b and 5c, respectively. It was found that the maximum MR_{SV} value measured in D-polymer OSV at very small V and low T reaches ˜330% (FIG. 5c). The measured MR hysteresis response seems to be very different in the two OSVs. Upon increasing B the MR jumps abruptly at B˜5 mT in the D-polymer OSV, consistent with H_{c1} of the LSMO electrode, whereas for the H-polymer OSV the MR increases more gradually, having an accelerated response at B˜10 mT. We also note the sharp MR_{SV} decrease with V for OSVs of both polymers, irrespective of the maximum MR_{SV} value obtained at V≈0. MR_{SV} decreases by an order of magnitude up to V=50 mV, follows by a more gentle decrease at higher voltage (FIG. 5c).

### Example 4

### Organic Light-Emitting Device

Magneto-electroluminescence, MEL; and magneto-conductance, MC, measurements were conducted on organic light emitting diodes (OLED). The devices used were 5 mm² diodes made from the D- and H-DOO-PPV polymer layer between a hole transport layer: poly(3,4-ethylenedioxythiophene) [PEDOT]-poly(styrene sulphonate) [PSS], and capped with a transparent anode: indium tin oxide [ITO], and a cathode: calcium (protected by aluminum film). The OLED structure was thus in the form of ITO/PEDOT:PSS/DOO—PPV/Ca/Al. The devices showed sizable electroluminescence (EL), which for biasing voltage V>V_{bi}(˜2 volt) approximately followed the device I-V characteristic. The devices were transferred to an optical cryostat with variable temperature that was placed in between the pole pieces of an electromagnet producing magnetic field, B up to 300 mT with 0.1 mT resolution. By increasing the distance between the two poles the resolution was improved down to 0.01 mT; in all cases B was determined with a calibrated magnetometer. The devices were driven at constant V using a Keithley 236 apparatus; and the current, I and EL intensity were simultaneously measured by the Keithley and a Si detector, respectively, while sweeping B. For comparing the field-induced current change, ΔI (MC) and induced EL change, ΔEL (MEL), ΔI/I and ΔEL/EL were simultaneously measured, which are defined according to the following equations:

$$Δ I / I = \frac{I ( B ) - I ( B = 0 )}{I ( B = 0 )} , Δ EL / EL = \frac{EL ( B ) - EL ( B = 0 )}{EL ( B = 0 )} .$$

With this definition MC>0 (MEL>0) when ΔI>0 (ΔEL>0).

FIGS. 6a and 6b show the magneto-electroluminescence (MEL) response of two OLED devices based on the H- and D-polymers (see Example 1) having the same thickness d_{f}, measured at the same bias voltage, V; very similar MC responses were also obtained. It is seen that the MEL (MC) response is narrower in the D-polymer device; the field, B_{1/2} at half the MEL maximum is about twice larger for the H-polymer device. In general, B_{1/2} increases with V (FIG. 5a inset); it increases approximately linearly with the device electric field, E=(V−V_{bi})/d_{f}, where V_{bi} is the built-in potential in the device, which is related to the onset V where EL and MEL are observed. In spite of this dependence with V, in all cases it was found that B_{1/2}(H)>B_{1/2}(D) for devices having the same E.

### Example 5

### Compass Device

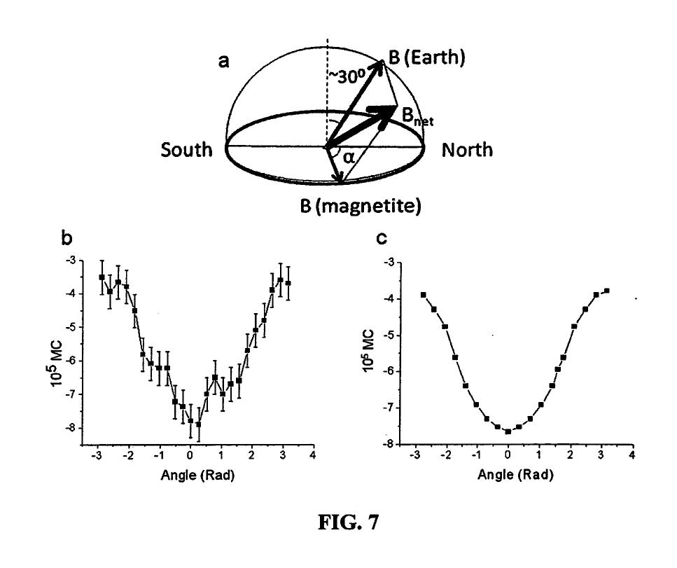

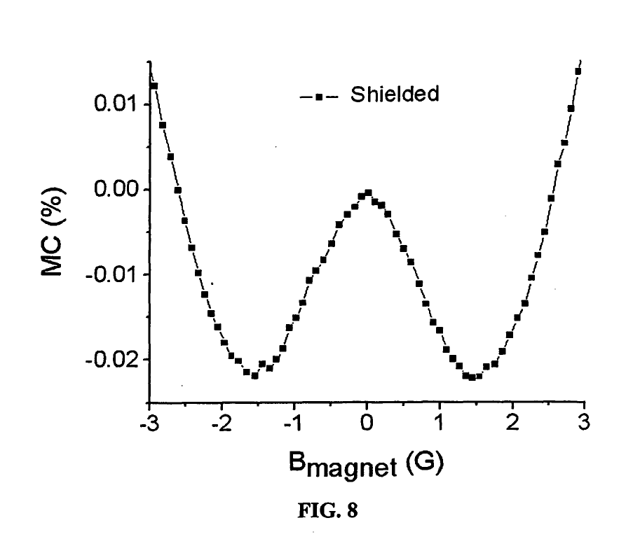

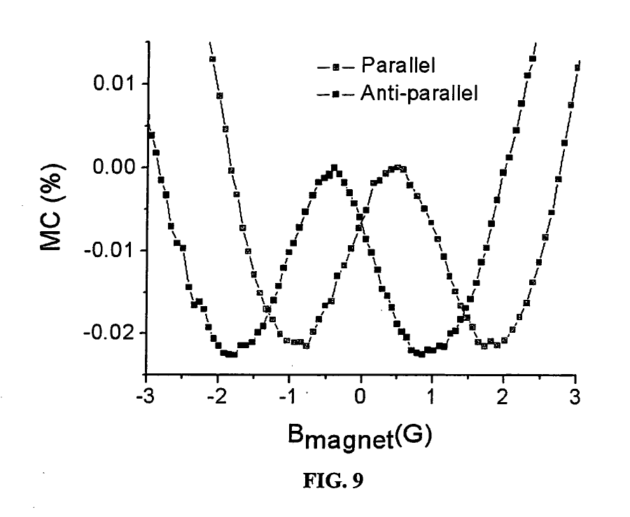

A compass device was engineered using an OLED based on deuterated DOO-PPV polymer as the active layer. The device was made of the following layers: ITO/PSS-DOTT/D-DOO-PPV/Ca/Al. Also attached to the device was a small magnet based on magnetite, which we refer to as the internal magnetic field. The compass magnetic configuration is shown in FIG. 7. The magnetoconductivity (MC) of the device reaches maximum negative when the internal magnetic field is aligned along the direction of the Earth magnetic field. It is possible to see the effect when measuring the electroluminescence (EL) from the device. The MEL also reaches minimum when the two fields (namely B(internal) and B(Earth) are aligned parallel to each other. The device may show the direction of B(Earth) when it reaches maximum MC (or MEL) decrease.

### Example 6

### Magnetometer Device for Ultra-Small Fields

A magnetometer based on the MC(B) response of an OLED based on D-DOO-PPV as described above was made and tested. FIG. 7 shows the MC(B) response of a shielded device. Without the earth magnetic field this device can accurately measure miniature fields in the range 0-1.5 Gauss with high sensitivity. For fields larger than 2.5 Gauss, MC(B) may be used for measuring field strength in the range of 2.5 to 1000 Gauss.

### CONCLUSION

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

Although several aspects of the present invention have been disclosed in the specification, it is understood by those skilled in the art that many modifications and other aspects of the invention will come to mind to which the invention pertains, having the benefit of the teaching presented in the foregoing description and associated drawings. It is thus understood that the invention is not limited to the specific aspects disclosed hereinabove, and that many modifications and other aspects are intended to be included within the scope of the appended claims. Moreover, although specific terms are employed herein, as well as in the claims which follow, they are used only in a generic and descriptive sense, and not for the purposes of limiting the described invention.

What is claimed is:

1. A device comprising:
first and second electrodes; and
an organic interlayer between the first and second electrodes, the organic interlayer comprising a deuterated organic material.

2. The device of claim 1, wherein the deuterated organic material has a deuterium atom: hydrogen atom ratio of at least 1:100.

3. The device of claim 1, wherein the deuterated organic material has a deuterium atom: hydrogen atom ratio of at least 10:100.

4. The device of claim 1, wherein the deuterated organic material has a deuterium atom: hydrogen atom ratio of from 1:0 to 0.1 for polymers, or 1 to 0.01 for small molecules.

5. The device of claim 1, wherein the deuterated organic material is not Alq₃-d₁₈.

6. The device of claim 1, wherein the deuterated organic material is non-metallic.

7. The device of claim 1, wherein the deuterated organic material consists of deuterium, carbon, and one or more elements selected from hydrogen, oxygen, nitrogen, and sulfur.

8. The device of claim 1, wherein the deuterated organic material is a π-conjugated polymer.

9. The device of claim 1, wherein the deuterated organic material is selected from partially or fully deuterated pentacenes, phthalocyanines, perylenes, quinolines, poly(p-phenylenevinylenes) (PPV), poly(thiopene)s, polyacetylenes, polypyrroles, polyanilines, and polyphenylene sulfides.

10. The device of claim 1, wherein the deuterated organic material is deuterated poly(dialkyloxy)phenyl vinylene.

11. The device of claim 1, wherein the deuterated organic material is deuterated poly(dioctyloxy)phenyl vinylene.

12. The device of claim 1, wherein the first and second electrodes are ferromagnetic.

13. The device of claim 1, wherein the first electrode is La_{0.67}Sr_{0.33}MnO₃ (LSMO) and the second electrode is cobalt (Co).

14. The device of claim 13, wherein the device has the structure La_{0.67}Sr_{0.33}MnO₃ (LSMO)/deuterated dioctyloxypolyphenylvinylidine (DOO-PPV)/Co.

15. The device of claim 1, wherein the device has the structure: Indium Tin Oxide (ITO)/poly(3,4-ethylenedioxythiophene) (PEDOT): poly(styrene sulphonate) (PSS)/deuterated dioctyloxypolyphenylvinylidine (DOO-PPV)/Ca/Al.

16. The device of claim 1, wherein the device has the structure: Indium Tin Oxide (ITO)/poly(styrene sulphonate) (PSS): poly(3,4-ethylenedioxythiophene) (PEDOT)/deuterated dioctyloxypolyphenylvinylidine (DOO-PPV)/LiF/Al.

17. The device of claim 16, further comprising a magnet attached to the device.

18. The device of claim 17, wherein the magnet comprises magnetite.

19. A method of forming a device, comprising:
forming a first electrode;
forming an organic interlayer on at least a portion of the first electrodes, the organic interlayer comprising a deuterated organic material; and
forming a second electrode, wherein said organic interlayer is at least partially between the first and second electrodes.
